(19) United States
(12) Patent Application Publication
(10) Pub. No.: US 2012/0262790 A1
(43) Pub. Date: Oct. 18, 2012

(54) ANTI-REFLECTIVE LENSES AND METHODS FOR MANUFACTURING THE SAME

(75) Inventors: Kai C. Su, Alpharetta, GA (US); Leslie F. Stebbins, Roswell, GA (US); Bill Mantch, Smyrna, GA (US); Eugene C. Letter, Webster, NY (US)

(73) Assignee: QSPEX TECHNOLOGIES, INC., Alpharetta, GA (US)

(21) Appl. No.: 13/088,199

(22) Filed: Apr. 15, 2011

(51) Int. Cl. G02B 1/11; C23C 16/40; B05D 5/06; B05D 1/36; B28B 7/36; C07F 7/10; C23C 16/50; B82Y 40/00

(52) U.S. Cl. 359/581; 556/413; 427/579; 427/162; 249/114.1; 359/601; 977/891; 977/890

(57) ABSTRACT

The present invention relates to a method of making an anti-reflective coating to an optical surface of a mold. In one embodiment, the method includes the steps of: providing a lens mold having an optical surface; forming a layer of a first hydrophobic material with a monolayer thickness over the optical surface; forming a layer of a second hydrophobic material with a thickness of about 10 to 50 nm over the layer of a first hydrophobic material, wherein the first and second hydrophobic materials are different; forming an anti-reflective coating layered structure over the layer of a second hydrophobic material; and forming a layer of a coupling agent that is deposited using vapor deposition and with a thickness of about 1 to 10 nm over the anti-reflective coating layered structure.

### CROSS-REFERENCE

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference were individually incorporated by reference.

### FIELD OF THE INVENTION

The present invention relates generally to an optical surface, and more particularly to an anti-reflective lens and methods of manufacturing the same.

### BACKGROUND OF THE INVENTION

An anti-reflective lens normally is formed with an antireflective coating on a plastic ophthalmic lens. Anti-reflective (AR) coatings are applied to the surface of ophthalmic lenses and other optical devices to reduce reflection. For ophthalmic lenses in particular, the reduced reflection makes them not only look better, but more importantly work better because they produce less glare by eliminating multiple reflections, which is particularly noticeable when driving at night or working in front of a computer monitor. The decreased glare means that wearers often find their eyes are less tired, particularly at the end of the day. AR coatings also allow more light to pass through the lens which increases contrast and therefore increases visual acuity.

The art of casting plastic ophthalmic lenses involves introducing a lens forming material between two molds and then polymerizing the lens forming material to become a solid. Liquid plastic formulations such as CR39 monomer are injected into a cavity formed by front and rear molds which have been provided with interior polished mold surfaces for the finished surfaces of the lenses. The plastic is cured in the mold and then the mold is separated to yield a completed ophthalmic lens which meets a selected prescription. The lens is then ground around the edge to fit into the selected frame. Coatings can be applied to the finished lens or to the inside of the front or rear mold, whereupon they will bond to the lens upon curing.

Some optometrists offer on-site eyeglass services. Several companies have developed methods by which lenses can be cast on site, in an office. However, current methods of applying AR coatings to eyeglasses require that they be shipped to a different facility because the AR coatings must be applied via vacuum vapor deposition. This of course means additional time and expense. There is therefore a need for a method for making eyeglasses with an AR coating on-site.

One type of AR coating that is used for ophthalmic lenses is an alternating stack of a high index material and a low index material. The most commonly used low index material is silicon dioxide; zirconium dioxide and/or titanium dioxide is often used as the high index material.

An issue with AR coatings, particularly as applied to plastic ophthalmic lenses, is adhesion. AR coatings are generally applied via vacuum deposition. It is well known that adhesion of vacuum deposited coatings to their substrates is in general problematic. The organic, plastic lens material and inorganic AR material do not readily adhere to each other, resulting in peeling or scratching. Accordingly, a new method is needed to apply an AR coating to a plastic lens with greater adhesion.

Several patents are understood to disclose using silanes to bind an inorganic matrix to an organic matrix. U.S. Pat. No. 5,733,483 to Soane et al. teaches using a coupling layer to tie together an AR multilayer made of silicon oxide and an acrylate containing lens. The coupling agent has a siloxy head and an acrylate tail. An example of silanes used therein is methacryloxypropyltrimethoxysilane.

U.S. Pat. No. 4,615,947 to Goosens teaches an acrylic mixed with an organopolysiloxane to increase the adhesion of an organosiloxane hardcoat to a thermoplastic substrate. U.S. Pat. No. 5,025,049 to Takarada et al. also teaches a primer for increasing adhesion of an organopolysiloxane layer to a thermoplastic substrate. The primer is a mixture of an organic copolymer including an alkoxysilylated monomer and other ingredients.

Other patents discuss using silanes to bind an organic matrix to another organic matrix. U.S. Pat. No. 6,150,430 to Walters et al. teaches using organofunctional silanes to improve the adherence of an organic polymeric layer to an organic polymeric substrate.

U.S. Pat. No. 5,096,626 to Takamizawa et al. teaches a plastic lens having an AR coating and/or hard coat. The patent discusses poor adhesion of prior art methods and say they achieve excellent adhesion by forming the lens using a set of molds, wherein the AR coating is first applied to one of the molds and then the lens monomer is poured between the molds and polymerized. A silane coupling agent, such as methacryloxypropyltrimethoxysilane can be included in the hard coat/AR coat solution which may contain colloidal silica, colloidal antimony oxide or colloidal titanium dioxide.

U.S. Pat. No. 6,986,857 to Klemm et al. teaches a method of assembling a lens with a top coat, AR coat, scratch resistant coat, impact resistant primer, and lens substrate. Klemm's solution to the issue of poor adherence of the top coat to the AR coat is to apply the first layer of the AR coating (which comprises a stack of four layers) as two sublayers of SiO₂. Another thin layer of SiO₂ is applied between the AR stack and the scratch resistant coating to improve adherence between the two.

The above references in general use sol gel chemistry and require high heat (≧80° C.). Heating to high temperature however is not suitable for casting and curing lenses in plastic molds because the optical surface of the mold will be distorted.

Therefore, a heretofore unaddressed need exists in the art to address the aforementioned deficiencies and inadequacies.

### SUMMARY OF THE INVENTION

In one aspect, the present invention relates to a method of applying an AR coating to a plastic substrate such as a plastic ophthalmic lens where the AR coating exhibits good adhesion to the substrate, wherein the method is practiced avoiding high or elevated temperatures.

In another aspect, the present invention relates to a method of on-site manufacturing of a plastic ophthalmic lens, particularly a spectacle lens having an AR coating.

In yet another aspect, the present invention relates to a method of making an anti-reflective coating to an optical surface of a mold. In one embodiment, the method includes the steps of:

providing a lens mold having an optical surface;

forming a layer of a first hydrophobic material with a thickness of about 10 to 30 nm over the optical surface;

forming a layer of a second hydrophobic material with a thickness of about 10 to 50 nm over the layer of a first hydrophobic material, wherein the first and second hydrophobic materials are different;

forming an anti-reflective coating layered structure over the layer of a second hydrophobic material; and

forming a layer of a silane coupling agent that is deposited using vapor deposition and aprotic conditions with a monolayer thickness over the anti-reflective coating layered structure.

The step of forming an anti-reflective coating layered structure over the layer of a second hydrophobic material can be performed with the steps of:

(1) forming a first layer of a first material with first index refraction and a thickness of about 5 to 100 nm over the layer of a second hydrophobic material;

(2) forming a second layer of a second material with second index refraction and a thickness of about 40 to 50 nm, to the first layer;

(3) forming a third layer of the first material with first index refraction and a thickness about 10 to 20 nm, to the second layer;

(4) forming a fourth layer of the second material with second index refraction and a thickness of about 50 to 70 nm, to the third layer;

(5) forming a fifth layer of the first material with first index refraction and a thickness of about 25 to 40 nm, to the fourth layer;

(6) forming a sixth layer of the second material with second index refraction and a thickness of about 10 to 25 nm, to the fifth layer; and

(7) forming a seventh layer of the first material with first index refraction and a thickness of about 5 to 15 nm, to the sixth layer.

In one embodiment, the first index refraction L and the second index refraction H satisfy a ratio of H/L>1. In other words, the value of the second index refraction is greater than the value of the first index refraction.

In one embodiment, the first material with first index refraction comprises SiO₂, and the second material with second index refraction comprises ZrO₂.

In practicing the present invention according to the methods set forth above, each layer of SiO₂ is deposited using ion assist or without using ion assist.

It is further noted that these anti-reflecting layers may be deposited by techniques known in the art such as resistance evaporation, electron beam evaporation, sputtering and other known techniques. In some cases it is desirable to ion assist the evaporation techniques by exposing the evaporation stream to a plasma of Argon or Oxygen during the deposition. On the other hand, in some other cases it is desirable not to ion assist the evaporation techniques.

In one embodiment, the first hydrophobic material is a standard hydrophobic material, and the second hydrophobic material is a super hydrophobic material, respectively.

In one embodiment, the layer of silane coupling agent is formed of a composition that comprises cyclic azasilanes. In one particular embodiment, the layer of coupling agent is formed of N-n-butyl-aza-2,2-dimethoxy-silacyclopentane.

In yet another aspect, the present invention relates to a mold with an optical surface having an anti-reflective coating that is transferable to an optical surface of a lens.

In various embodiments, such a mold has:

a layer of a first hydrophobic material with a thickness of about 10 to 30 nm deposited over an optical surface the mold;

a layer of a second hydrophobic material with a thickness of about 10 to 50 nm deposited over the layer, wherein the first and second hydrophobic materials are different;

an anti-reflective coating layered structure deposited over the layer; and

a layer of a coupling agent that is deposited using vapor deposition under aprotic conditions, with a monolayer thickness deposited over the anti-reflective coating layered structure.

The first hydrophobic material is a standard hydrophobic material, and the second hydrophobic material is a super hydrophobic material, respectively.

The layer of coupling agent is formed of a composition that comprises cyclic azasilanes. In various embodiments, the layer of coupling agent is formed of N-n-butyl-aza-2,2-dimethoxy-silacyclopentane.

In a further aspect, the present invention relates to an optical lens. The optical lens has a lens body with an optical surface and an anti-reflective coating formed on the optical surface, where in various embodiments, the anti-reflective coating has:

a layer of a first hydrophobic material with a thickness of about 10 to 30 nm deposited over an optical surface of the mold;

a layer of a second hydrophobic material with a thickness of about 10 to 50 nm deposited over the layer of the first hydrophobic material, wherein the first and second hydrophobic materials are different;

an anti-reflective coating layered structure deposited over the layer of the second hydrophobic material; and

a layer of a silane coupling agent that is deposited using vapor deposition under aprotic conditions and a monolayer thickness deposited over the anti-reflective coating layered structure and coupled to the optical surface.

In yet another aspect, the present invention relates to a coupling agent usable in lens making. In one embodiment, the silane coupling agent comprises cyclic azasilanes. In one specific embodiment, cyclic azasilanes comprise N-n-butyl-aza-2,2-dimethoxy-silacyclopentane.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

FIG. 1 shows chemical reactions related to coupling agents utilized in prior art for manufacturing an anti-reflective coated lens.

FIG. 2 shows chemical reactions related to coupling agents utilized for manufacturing an anti-reflective coated lens according to one embodiment of the present invention.

FIG. 3 shows preparation of an anti-reflective coated lens mold according to one embodiment of the present invention.

FIG. 4 shows preparation of an anti-reflective coated lens mold according to one embodiment of the present invention.

FIG. 5 shows preparation of an anti-reflective coated lens mold according to one embodiment of the present invention.

FIG. 6 shows preparation of an anti-reflective coated lens mold according to one embodiment of the present invention.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like parts throughout the views. As used in the description herein and throughout the claims that follow, the meaning of “a,” “an,” and “the” includes plural reference unless the context clearly dictates otherwise. Also, as used in the description herein and throughout the claims that follow, the meaning of “in” includes “in” and “on” unless the context clearly dictates otherwise.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. The use of examples anywhere in this specification, including examples of any terms discussed herein, is illustrative only, and in no way limits the scope and meaning of the invention or of any exemplified term. Likewise, the invention is not limited to various embodiments given in this specification.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

### Overview of the Invention

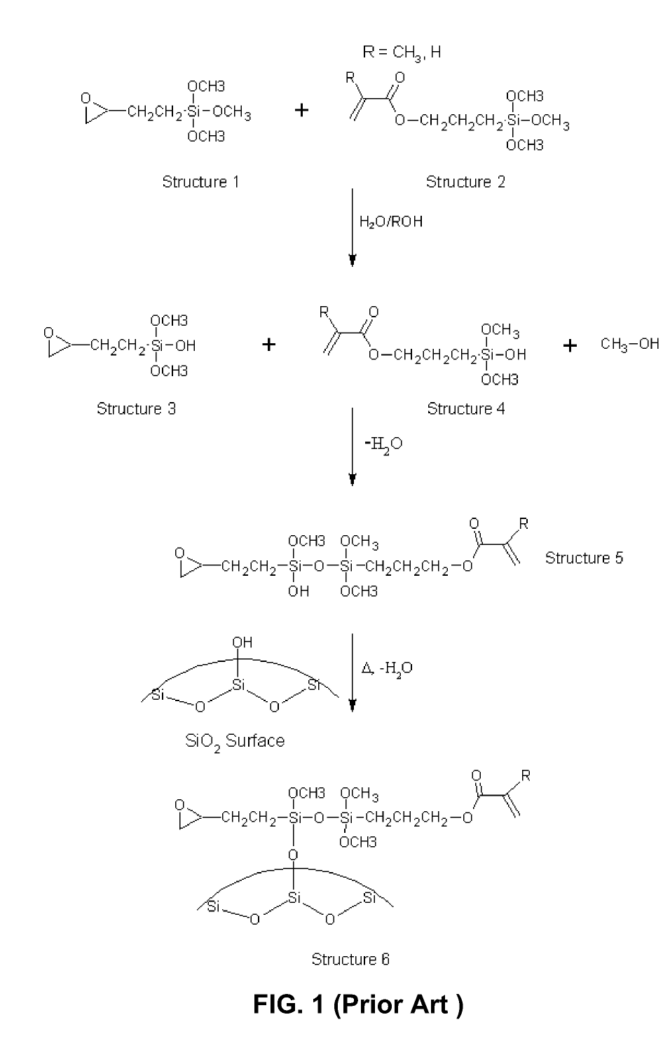

The description will be made as to the embodiments of the present invention in conjunction with the accompanying drawings in FIGS. 1-6. In accordance with the purposes of this invention, as embodied and broadly described herein, this invention, relates to AR coated spectacle lenses, compositions and methods of making AR lenses.

According to various embodiments of the present invention, a layer of SiO₂ is applied to a clean optical surface of a plastic mold by vapor deposition. A hydrophobic coating layer is then applied in the same manner, followed by a super-hydrophobic coating layer. No mold release coating is needed or desirable. Subsequent to the hydrophobic coatings, an anti-reflective (AR) coating is applied. The AR coating is a layered structure with multiple layers of dielectric materials (4 to 7 layers or even more) that are applied by vacuum deposition such that the first and last layer are ion-assisted SiO₂. Preferably, the anti-reflective coating is a layered structure with multiple layers of three or more dielectric materials having alternating high and low refractive indexes.

A layer of cyclic azasilane as a silane coupling agent is applied to the AR-coated mold to promote adhesion of the hard coating. The coupling agent layer can be applied under dry, aprotic conditions. This can be done using methods commonly practiced in the lens industry today (such as spin, spray, dip, vacuum coating). The silane from the coupling agent will bond to the anti-reflective coating and the functional group will bond with the organic hard coat, respectively. The coupling agent layer is applied at room temperature.

The next coating layer applied to the mold is the scratch-resistant (hard) coating. The hard coat can be applied by conventional methods used in the lens industry, including spin, spray, or dip coating followed by curing.

The exemplary process illustrated above can be repeatedly applied to different optical surfaces of an optical mold assembly containing a front mold and a back mold. Following the applications of the coating to both of the front and back molds, they are assembled with a spacer ring to form the optical mold assembly. The cavity of the assembly is then filled with lens material formulation and cured. After the cure is complete, the lens is removed from the assembly. All coatings are transferred to the lens so that the lens has hydrophobic, anti-reflective, and scratch resistance coatings applied. This process may also be used to make polarized and photochromic lenses.

Thus, in one aspect, more specifically, the invention relates to a method for making an AR coated plastic substrate having good adhesion of the AR coating. The plastic substrate in one embodiment is a plastic ophthalmic lens.

In another aspect, the invention relates to a method of making AR coated plastic ophthalmic lenses on-site.

An AR coating is commonly applied to the surface of lenses to reduce reflection. Often, the AR coating is made of multiple layers of high index and low index materials such as ZrO₂ and SiO₂. One problem with inorganic silica AR coatings is that they do not readily adhere to plastic organic lenses. The present invention successfully solves the problem by, among other things, using a coupling layer between the inorganic silica AR coating and the lens. In one embodiment of the present invention, the coupling layer is formed by utilizing cyclic azasilane.

In general, the method for forming an ophthalmic lens having an AR coating thereon is comprised of the steps of preparing first and second molds having polished optical surfaces facing each other. In a preferred embodiment, molds and a gasket such as described in U.S. Pat. No. 7,114,696 are used. Various desired coatings are applied to the interior of one or both molds. The molds with the coatings thereon are placed in a gasket assembly which provides a space between the molds. A liquid monomer is placed in the space and is cured to provide a lens.

The molds can be formed of any suitable material which is capable of withstanding the processing temperatures hereinafter utilized and which can provide polished surfaces of the type required for the optical elements being prepared.

In one embodiment of the present invention, as a first step, a coating is applied by electron beam deposition directly onto the plastic mold optical surface. Subsequent to the first coating, a second coating may be applied before a multilayer AR coating is applied in reverse order. In one embodiment of the present invention, an AR coating is a multilayer structure with alternating layers formed with two different materials, a high index material and a low index material. In one preferred embodiment of the present invention, an AR coating is a multilayer structure with 7 alternating layers formed with two different materials, a high index material H and a low index material L with a ratio H/L>1. Materials found to be suitable for practicing the present invention are zirconium dioxide (referred as “ZrO₂”) as a high index material and silicon dioxide as a low index material, having an index of refraction of approximately 1.46.

In one embodiment of the present invention, the layers are applied by vacuum deposition such that the first and last layers are silicon dioxide (SiO₂). It is preferred that the AR chamber be humidified during application of the last layer of silicon oxide.

Following the AR coating application, a layer or film of the coupling agent cyclic azasilane is applied by vapor phase deposition. The cyclic azasilane will bond to surface hydroxyls on the silicon dioxide layer, opening the ring and resulting in an organic molecule on the surface. This can be done under vacuum, at room temperature, and does not require water as a catalyst.

Next, a scratch resistant (hard) coating is applied. The hard coat can be applied as either an extension of the AR coating process by vacuum deposition or by the more conventional methods of spin, spray, or dip coating with the coating application followed by curing.

Following the application of the various coatings to the mold, a front and back mold are assembled. The cavity of the assembly is then filled with lens material formulation which is then cured and bonds to the hard coat. After the cure is complete the lens is removed from the assembly. All coatings are transferred to the lens so that the lens has hydrophobic, anti-reflective, and scratch resistance coatings applied.

Cyclic azasilanes are available from Gelest, Inc. Generic formulas include azasilacyclopentanes having the formula:

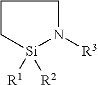

where R¹ and R² are independently selected from the group consisting of branched and linear, substituted and unsubstituted alkyl, alkenyl and alkoxy groups, and where R³ is selected from the group consisting of substituted and unsubstituted, saturated and unsaturated, branched and linear aliphatic hydrocarbon groups, substituted and unsubstituted, branched and linear aralkyl groups, substituted and unsubstituted aryl groups, and hydrogen, and diazasilacyclic compounds. Diazasilacyclic compounds have the formula:

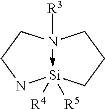

where the R³ are independently selected (i.e., they may be the same or different) from the group consisting of substituted and unsubstituted, saturated and unsaturated, branched and linear aliphatic hydrocarbon groups; substituted and unsubstituted, branched and linear aralkyl groups; substituted and unsubstituted aryl groups; and hydrogen; and wherein R₄ and R₅ are independently selected from the group consisting of substituted and unsubstituted, branched and linear alkyl and alkoxy groups.

These and other aspects of the present invention are more specifically described below.

### IMPLEMENTATIONS AND EXAMPLES OF THE INVENTION

Without intent to limit the scope of the invention, additional exemplary embodiment and their related results according to the embodiments of the present invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as the invention is practiced according to the invention without regard for any particular theory or scheme of action.

### EXAMPLE 1

### Cyclic Azasilanes

Various types of cyclic azasilanes can be used to practice the present invention, including:

(a) SIB 1932.4 or N-n-BUTYL-AZA-2,2-DIMETHOXYSILACYCLOPENTANE, C9H21NO2Si, with the following formula:

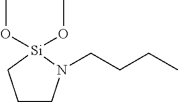

(b) SID3543.0 or 2,2-DIMETHOXY-1,6-DIAZA-2-SILACYCLOOCTANE, C7H18N2O2Si, with the following formula:

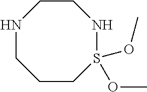

(c) SIA0592.0 or N-AMINOETHYL-AZA-2,2,4-TRIMETHYLSILACYCLOPENTANE, C8H21NSi, with the following formula:

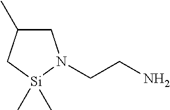

(d) SIA0380.0 or N-ALLYL-AZA-2,2-DIMETHOXYSILACYCLOPENTANE C8H17NO2Si, with the following formula:

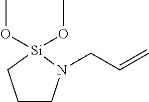

### EXAMPLE 2

### Coating Bonding Tests

This example shows various tests utilized for coating bonding produced according to various embodiments of the present invention.

Cross-Hatch Test. In the cross-hatch test, a series of 10 lines spaced 1 mm apart is cut into the coating with a razor blade. A second series of 10 lines spaced 1 mm apart at right angles to and overlaying the first is cut into the coating. A piece of cellophane tape is then applied over the crosshatch pattern and pulled quickly away from the coating.

Crazing Test. In the crazing test, a lens is de-molded then annealed at 80° C. for 20 minutes. The lens is quickly transferred to room temperature water and it is checked for crazing. If no crazing is apparent, then the AR/coupling agent system is acceptable.

Boiling Salt Water Test. In the boiling salt water test, the lens is first immersed for two minutes in a boiling salt solution containing 4.5% NaCl and 0.8% NaH₂PO₄.2H₂O. Next, the lens is quickly transferred to room temperature (18-24° C.) deionized water. If no crazing or delamination in the coating is noted, then the AR/coupling agent system is acceptable.

### EXAMPLE 3

### Preparation of an Ar Coating that is Applied to a Disposable Mold

In this Example, among other things, a process of preparation of applying an AR coating to a disposable mold is provided according to one embodiment of the present invention. It is noted that in this Example, SiO₂ layers are formed or deposited with or without ion assist.

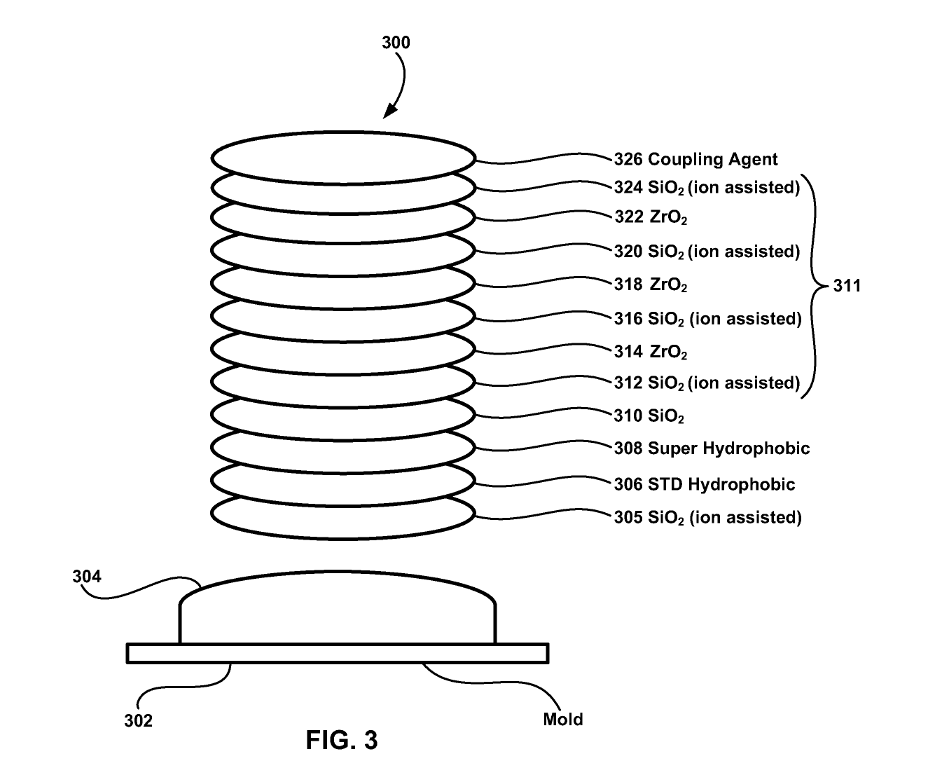

Referring now to FIG. 3, the processes described below are performed with a standard box coater and an electron beam for evaporation in connection with a mold 302 having an optical surface 304. The processes are done by using well known vacuum practices.

Procedure:

(1) Cleaning the optical surface 304 of the mold 302. In one embodiment of the present invention, a plasma cleaning is performed on the mold surface for about 2 min.

(2) Forming a layer 305 of SiO₂ that is ion assisted with a thickness of 5 to 100 nm to the optical surface 304.

(3) Forming a layer 306 of a standard hydrophobic material with a thickness of about 10 to 30 nm to the layer 305.

(4) Forming a layer 308 of a super hydrophobic material with a thickness of about 10 to 50 nm to the layer 306.

(5) Forming a layer 310 of SiO₂ that is deposited without using ion assist and with a thickness of about 5 to 40 nm to the layer 308.

(6) Forming a layer 312 of SiO₂ that is deposited using ion assist and with a thickness of about 5 to 100 nm to the layer 310.

(7) Forming a layer 314 of ZrO₂ with a thickness of about 40 to 50 nm to the layer 312.

(8) Forming a layer 316 of SiO₂ that is deposited using ion assist and with a thickness about 10 to 20 nm to the layer 314.

(9) Forming a layer 318 of ZrO₂ with a thickness of about 50 to 70 nm to the layer 316.

(10) Forming a layer 320 of SiO₂ that is deposited using ion assist and with a thickness of about 25 to 40 nm to the layer 318.

(11) Forming a layer 322 of ZrO₂ with a thickness of about 10 to 25 nm to the layer 320.

(12) Forming a layer 324 of SiO₂ that is deposited using ion assist and with a thickness of about 5 to 15 nm to the layer 322.

(13) Forming a layer 326 of a coupling agent that is deposited using vapor deposition and with a monolayer of thickness to the layer 324.

It is noted that in this embodiment, the layer 306 of a standard hydrophobic material and layer 308 of a super hydrophobic material do not adherent or stick to each other; thus, when the layered structure is transferred to an optical surface of a lens during lens making process, the layer 306 of a standard hydrophobic material and the layer 308 of a super hydrophobic material will separate, resulting in that the layer 308 of a super hydrophobic material, at least in part, will become the outmost layer of the optical lens. It is noted that, however, the outmost layer of the optical lens will be a layer of hydrophobic material that likely contains the super hydrophobic material, may be a major portion of the later, as well as the standard hydrophobic material, may be a minor portion of the layer. The layer 306 of a standard hydrophobic material, at least in part, will adherent or stick to the layer 305 of SiO₂. It is also noted that, some materials from layer 308 of a super hydrophobic material may also adherent or stick to the layer 305 of SiO₂. Moreover, layer 310 of SiO₂ functions as a protective seal to the AR layered structure 311 and also as natural bonding or a “link” between the AR layered structure 311 and the layer 308 of a super hydrophobic material. Likewise, layer 324 of SiO₂ provides a natural bonding or “link” between the AR layered structure 311 and the layer 326 of coupling agent. It is noted that although layer 310 and layer 312 both are formed of SiO₂, they are formed with different processes such that they adherent to each other but function differently.

### EXAMPLE 4

### Preparation of an Ar Coating that is Applied to a Disposable Mold

In this Example, among other things, a process of preparation of applying an AR coating to a disposable mold is provided according to another embodiment of the present invention. It is noted that in this Example, SiO₂ layers are formed or deposited with ion assisted.

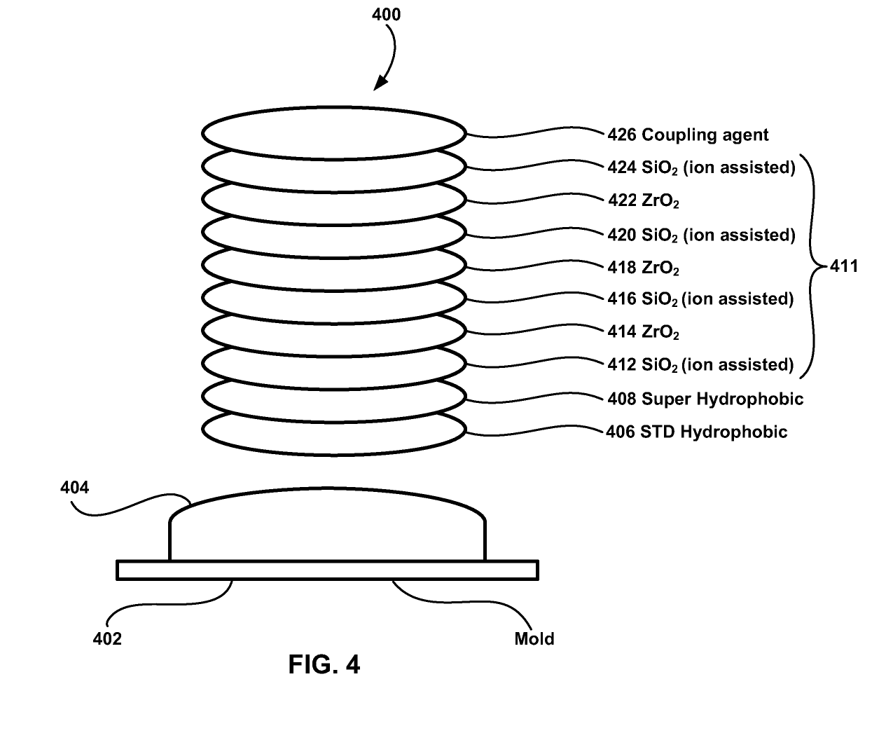

Referring now to FIG. 4, the processes described below are performed with a standard box coater and an electron beam for evaporation in connection with a mold 402 having an optical surface 404. The processes are done by using well known vacuum practices.

Procedure:

(1) Cleaning the optical surface 404 of the mold 402. In one embodiment of the present invention, a plasma cleaning is performed on the mold surface for about 2 min.

(2) Forming a layer 406 of a standard hydrophobic material with a thickness of about 10 to 30 nm to the optical surface 404.

(3) Forming a layer 408 of a super hydrophobic material with a thickness of about 10 to 15 nm to the layer 406.

(4) Forming a layer 412 of SiO₂ that is deposited using ion assist and with a thickness of about 60 to 120 nm to the layer 408.

(5) Forming a layer 414 of ZrO₂ with a thickness of about 40 to 50 nm to the layer 412.

(6) Forming a layer 416 of SiO₂ that is deposited using ion assist and with a thickness about 10 to 20 nm to the layer 414.

(7) Forming a layer 418 of ZrO₂ with a thickness of about 50 to 70 nm to the layer 416.

(8) Forming a layer 420 of SiO₂ that is deposited using ion assist and with a thickness of about 25 to 40 nm to the layer 418.

(9) Forming a layer 422 of ZrO₂ with a thickness of about 10 to 25 nm to the layer 420.

(10) Forming a layer 424 of SiO₂ that is deposited using ion assist and with a thickness of about 5 to 15 nm to the layer 422.

(11) Forming a layer 426 of a coupling agent that is deposited using vapor deposition and with a monolayer thickness to the layer 424.

### EXAMPLE 5

### Preparation of an Ar Coating that is Applied to a Disposable Mold

In this Example, among other things, a process of preparation of applying an AR coating to a disposable mold is provided according to yet another embodiment of the present invention. It is noted that in this Example, SiO₂ layers are formed or deposited with or without ion assist.

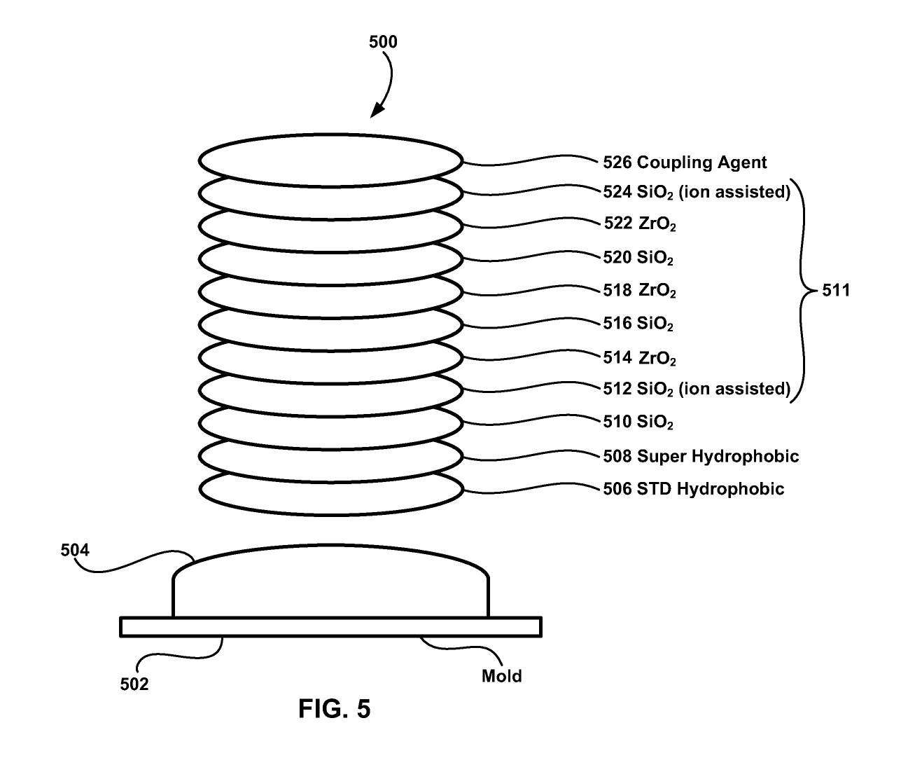

Referring now to FIG. 5, the processes described below are performed with a standard box coater and an electron beam for evaporation in connection with a mold 502 having an optical surface 504. The processes are done by using well known vacuum practices.

Procedure:

(1) Cleaning the optical surface 504 of the mold 502. In one embodiment of the present invention, plasma cleaning is performed on the mold surface for about 2 min.

(2) Forming a layer 506 of a standard hydrophobic material with a thickness of about 10 to 30 nm to the optical surface 504.

(3) Forming a layer 508 of a super hydrophobic material with a thickness of about 10 to 50 nm to the layer 506.

(4) Forming a layer 510 of SiO₂ that is deposited without using ion assist and with a thickness of about 5 to 40 nm to the layer 508.

(5) Forming a layer 512 of SiO₂ that is deposited using ion assist and with a thickness of about 5 to 100 nm to the layer 510.

(6) Forming a layer 514 of ZrO₂ with a thickness of about 40 to 50 nm to the layer 512.

(7) Forming a layer 516 of SiO₂ that is deposited without using ion assist and with a thickness about 10 to 20 nm to the layer 514.

(8) Forming a layer 518 of ZrO₂ with a thickness of about 50 to 70 nm to the layer 516.

(9) Forming a layer 520 of SiO₂ that is deposited without using ion assist and with a thickness of about 25 to 40 nm to the layer 518.

(10) Forming a layer 522 of ZrO₂ with a thickness of about 10 to 25 nm to the layer 520.

(11) Forming a layer 524 of SiO₂ that is deposited using ion assist and with a thickness of about 5 to 15 nm to the layer 522.

(12) Forming a layer 526 of a coupling agent that is deposited using vapor deposition and with a monolayer thickness to the layer 524.

### EXAMPLE 6

### Preparation of an Ar Coating that is Applied to a Disposable Mold

In this Example, among other things, a process of preparation of applying an AR coating to a disposable mold is provided according to a further embodiment of the present invention. It is noted that in this Example, SiO₂ layers are formed or deposited with or without ion assist.

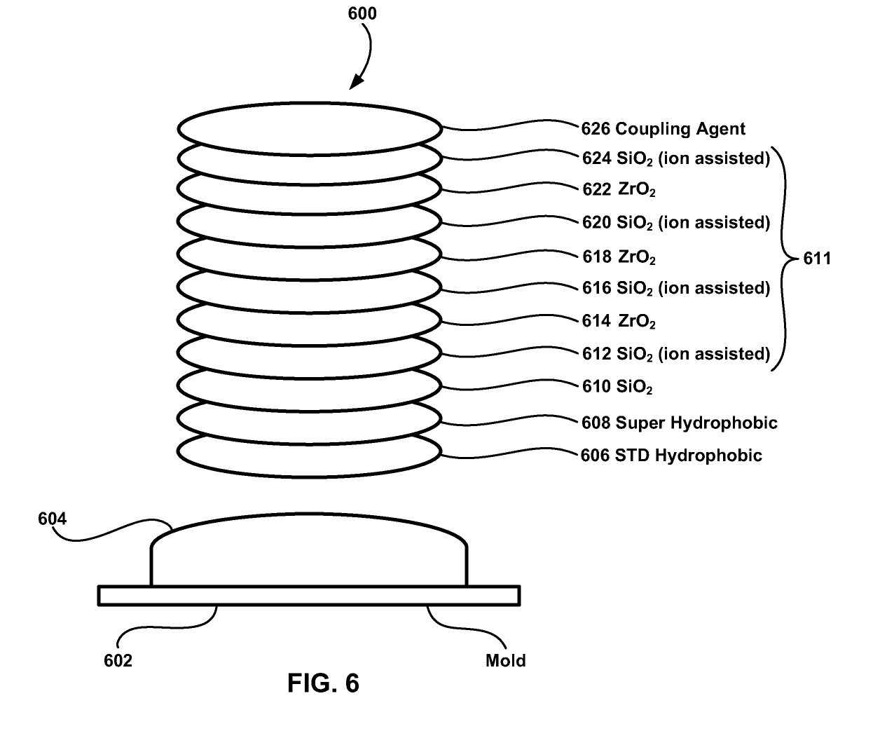

Referring now to FIG. 6, the processes described below are performed with a standard box coater and an electron beam for evaporation in connection with a mold 602 having an optical surface 604. The processes are done by using well known vacuum practices.

Procedure:

(1) Cleaning the optical surface 604 of the mold 602. In one embodiment of the present invention, plasma cleaning is performed on the mold surface for about 2 min.

(2) Forming a layer 606 of a standard hydrophobic material with a thickness of about 10 to 30 nm to the optical surface 604.

(3) Forming a layer 608 of a super hydrophobic material with a thickness of about 10 to 50 nm to the layer 606.

(4) Forming a layer 610 of SiO₂ that is deposited without using ion assist and with a thickness of about 5 to 40 nm to the layer 608.

(5) Forming a layer 612 of SiO₂ that is deposited using ion assist and with a thickness of about 5 to 100 nm to the layer 610.

(6) Forming a layer 614 of ZrO₂ with a thickness of about 40 to 50 nm to the layer 612.

(7) Forming a layer 616 of SiO₂ that is deposited using ion assist and with a thickness about 10 to 20 nm to the layer 614.

(8) Forming a layer 618 of ZrO₂ with a thickness of about 50 to 70 nm to the layer 616.

(9) Forming a layer 620 of SiO₂ that is deposited using ion assist and with a thickness of about 25 to 40 nm to the layer 618.

(10) Forming a layer 622 of ZrO₂ with a thickness of about 10 to 25 nm to the layer 620.

(11) Forming a layer 624 of SiO₂ that is deposited using ion assist and with a thickness of about 5 to 15 nm to the layer 622.

(12) Forming a layer 626 of a coupling agent that is deposited using vapor deposition and with a monolayer thickness to the layer 624.

### EXAMPLE 7

### Preparation and Application of Coupling Agent

In the Examples 3-6, among other things, the present invention is practiced with a layer of a coupling agent is applied to the AR-coated mold to promote adhesion of the hard coating.

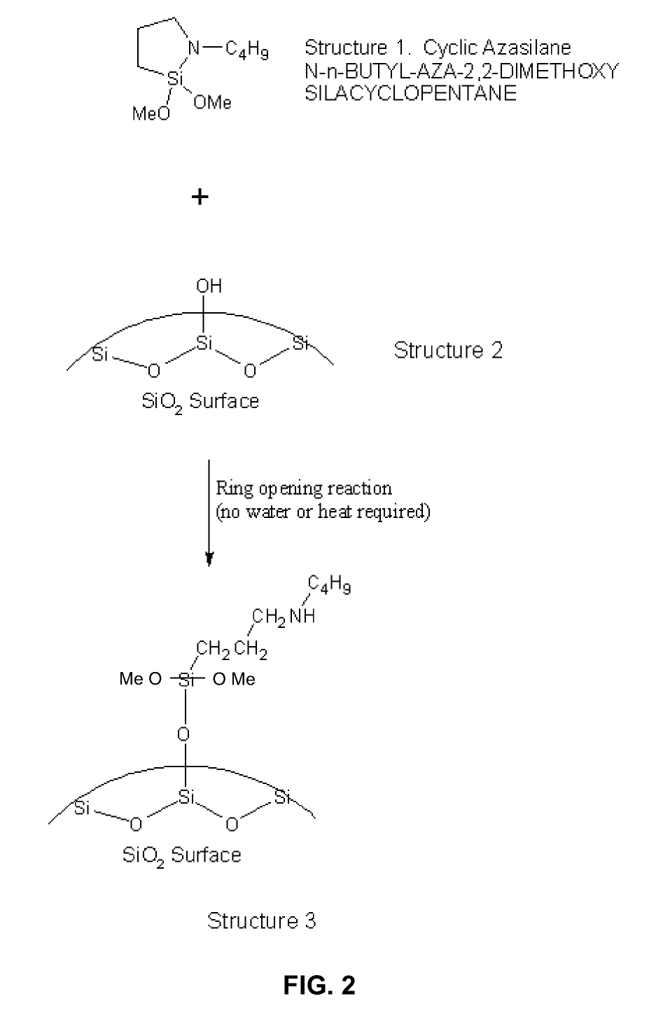

Material-wise, the coupling agents are functional silanes in which the silane bonds to the anti-reflective coating and the functional group bonds with the organic hard coat. According to one embodiment of the present invention, cyclic azasilanes are particularly well suited for the application, as they will form silane bonds at room temperature via a ring-opening reaction. This results in a monolayer with functional groups that readily attach to the hard coat, forming a strong AR to hard-coat bond. It is believed that it is the first time in the industry and only by the inventive discovery of the present invention, that cyclic azasilanes are utilized in optical lens forming process as coupling agents. For embodiments as shown in FIGS. 3-6, where SiO₂ is used as the first material with first index refraction, utilizing N-n-butyl-aza-2,2-dimethoxy-silacyclopentane as a silane coupling agent allows a surface bonding ring opening reaction without requiring water or heat, as shown in FIG. 2, resulting in much better bonding and making the on-site AR lens forming a reality.

Procedure-wise, the coupling agent can be applied under dry, aprotic conditions and can be done using many of the methods commonly practiced in the lens industry today, such as spin, spray, dip, and vacuum coating. Two specific examples of coupling agent application are provide below.

A. Vacuum Coating—Procedure:
(1) An optical mold assembly containing a front mold and a back mold, where corresponding optical surfaces of the molds are AR-coated molds according to one of various embodiments of the present invention as illustrated in Examples 3-6, is placed in a vacuum chamber, which is evacuated to create a dry, aprotic environment with a predetermined pressure, in which a coupling agent will vaporize when introduced into the chamber.
(2) The coupling agent is introduced into the sealed chamber and allowed to coat and react with each AR coating for a minimum of 10 minutes.
(3) The chamber is evacuated to the original (pre-coupling agent), predetermined pressure to remove excess coupling agent.
(4) The vacuum is released and the optical mold assembly is removed from the chamber. Afterwards, a hard coat can be applied.

B. Dip Coating—Procedure:
(1) A solution of coupling agent in an aprotic solvent is prepared (0.05% minimum). Examples of aprotic solvents include toluene, benzene, petroleum ether, or other hydrocarbon solvents.
(2) An AR-coated mold, prepared according to one of various embodiments of the present invention as illustrated in Examples 3-6, is exposed to (or treated with) the solution for a minimum of 5 minutes at room temperature.
(3) The treated mold is removed from the solution and rinsed with ethanol or a similar solvent.
(4) The mold is then air-dried and afterwards a hard coat can be applied.

### EXAMPLE 8

### Procedure for Making an Ar-Coated Lens

This example shows a method or procedure of making an AR-coated lens according to one embodiment of the present invention.

The corresponding optical surfaces of a front mold and a back mold of an optical mold assembly were AR-coated according to the one embodiment of the present invention illustrated in Example 3. A layer (326) of a coupling agent consisting of or having N-n-butyl-aza-2,2-dimethoxy-silacyclopentane was then formed onto the AR surfaces (324) using a dip coating method as set forth above in Example 7. A solution was prepared of 0.2% coupling agent in petroleum ether. The optical surfaces were submerged in the solution for 5 minutes at room temperature. They were then rinsed with ethanol, blown dry with an air gun, and hard-coated within one hour using a spin-coating process. Upon lens monomer casting and curing, the AR and super-hydrophobic coatings transferred from the mold onto the lens.

### EXAMPLE 9

### Procedure for Making an Ar-Coated Lens

This example shows a method or procedure of making an AR-coated lens according to one embodiment of the present invention.

The corresponding optical surfaces of a front mold and a back mold of an optical mold assembly were AR-coated according to the one embodiment of the present invention illustrated in one of Examples 4-6. A layer (426, 526, 626) of a coupling agent consisting of or having N-n-butyl-aza-2,2-dimethoxy-silacyclopentane was then formed onto the AR surfaces (424, 524, 624) using a dip coating method as set forth above in Example 7. A solution was prepared of 0.05% coupling agent in petroleum ether. The optical surfaces were submerged in the solution for 5 minutes at room temperature. They were then rinsed with ethanol, allowed to air-dry, and immediately hard-coated using a spin-coating process. Upon casting, the AR and super-hydrophobic coatings transferred from the mold onto the lens.

### EXAMPLE 10

### Procedure for Making an Ar-Coated Lens

This example shows a method or procedure of making an AR-coated lens according to one embodiment of the present invention.

The corresponding optical surfaces of a front mold and a back mold of an optical mold assembly were AR-coated according to the one embodiment of the present invention illustrated in Example 3. The optical mold assembly with AR-coated optical surfaces was then placed on the floor of a vacuum chamber under a predetermined pressure of about −28.6 in. Hg. About 0.2mL of the N-n-butyl-aza-2,2-dimethoxy-silacyclopentane was injected into the chamber and vaporized under the predetermined pressure. The N-n-butyl-aza-2,2-dimethoxy-silacyclopentane was given 10 minutes to react with the AR-coated surfaces to form a layer of a coupling agent then on, after which the vacuum pump was turned on for 5 minutes in order to remove any excess coupling agent. Molds were then immediately hard-coated and cast into lenses. The AR and super-hydrophobic coatings transferred from the mold onto the lens.

### EXAMPLE 11

### Procedure for Making an Ar-Coated Lens

This example shows a method or procedure of making an AR-coated lens according to one embodiment of the present invention.

The corresponding optical surfaces of a front mold and a back mold of an optical mold assembly were AR-coated according to the one embodiment of the present invention illustrated in Example 3. The optical mold assembly with AR-coated optical surfaces was then placed on the floor of a vacuum chamber under a predetermined pressure of about −28.6 in. Hg. 0.05 mL of the N-n-butyl-aza-2,2-dimethoxy-silacyclopentane coupling agent was injected into the chamber and vaporized under the predetermined pressure. The coupling agent was given 10 minutes to react with the AR coated optical surfaces, after which the vacuum pump was turned on for 5 minutes in order to remove any excess coupling agent. Molds were then immediately hard-coated and lens monomer cast and cured into lenses. The AR and super-hydrophobic coatings transferred from the mold onto the lens.

### EXAMPLE 12

### Procedure for Making an Ar-Coated Lens

This example shows a method or procedure of making an AR-coated lens according to one embodiment of the present invention.

The corresponding optical surfaces of a front mold and a back mold of an optical mold assembly were AR-coated according to the one embodiment of the present invention illustrated in Example 3. The optical mold assembly with AR-coated optical surfaces was then placed on the floor of a vacuum chamber under a predetermined pressure of about −28.6 in. Hg. A solution was prepared with 10% of N-n-butyl-aza-2,2-dimethoxy-silacyclopentane coupling agent in hexane. 0.1 mL of the solution (0.01 mL of the coupling agent) was injected into the chamber and vaporized under the predetermined pressure. The coupling agent was given 10 minutes to react with the AR surfaces, after which the vacuum pump was turned on for 5 minutes in order to remove any excess coupling agent. Molds were then immediately hard-coated and cast into lenses. The AR and super-hydrophobic coatings transferred from the mold onto the lens.

Thus, in another aspect, the present invention relates to a method of making an anti-reflective coating to an optical surface of a mold. In one embodiment, referring to FIG. 3, the method includes the steps of:

providing a lens mold 302 having an optical surface 304;

forming a layer 305 of SiO₂ that is ion assisted with a thickness of 5 to 100 nm to the optical surface 304;

forming a layer 306 of a first hydrophobic material with a thickness of about 10 to 30 nm to the layer 305;

forming a layer 308 of a second hydrophobic material with a thickness of about 10 to 50 nm to the layer 306, wherein the first and second hydrophobic materials are different;

forming a layer 310 of SiO₂ that is deposited without using ion assist and with a thickness of about 5 to 40 nm to the layer 308;

forming an anti-reflective coating layered structure 311 to the layer 310; and

forming a layer 326 of a coupling agent that is deposited using vapor deposition and with a monolayer thickness to the layer 324.

In the embodiment shown in FIG. 3, the anti-reflective coating layered structure 311 to the layer 310 can be formed by the steps of:

(1) forming a layer 312 of SiO₂ that is deposited using ion assist and with a thickness of about 5 to 100 nm to the layer 310;

(2) forming a layer 314 of ZrO₂ with a thickness of about 40 to 50 nm to the layer 312;

(3) forming a layer 316 of SiO₂ that is deposited using ion assist and with a thickness about 10 to 20 nm to the layer 314;

(4) forming a layer 318 of ZrO₂ with a thickness of about 50 to 70 nm to the layer 316;

(5) forming a layer 320 of SiO₂ that is deposited using ion assist and with a thickness of about 25 to 40 nm to the layer 318;

(6) forming a layer 322 of ZrO₂ with a thickness of about 10 to 25 nm to the layer 320; and

(7) forming a layer 324 of SiO₂ that is deposited using ion assist and with a thickness of about 5 to 15 nm to the layer 322.

In one embodiment, the first hydrophobic material is a standard hydrophobic material, and the second hydrophobic material is a super hydrophobic material, respectively.

In one embodiment, the layer of coupling agent is formed of a composition that comprises cyclic azasilanes.

More specifically, in one embodiment, the layer of coupling agent is formed of N-n-butyl-aza-2,2-dimethoxy-silacyclopentane.

Furthermore, in a more general embodiment, the anti-reflective coating layered structure 311 to the layer 310 can be formed by the steps of:

(1) forming a layer 312 of a first material with first index refraction, which is deposited using ion assist and with a thickness of about 5 to 100 nm, to the layer 310;

(2) forming a layer 314 of a second material with second index refraction, with a thickness of about 40 to 50 nm, to the layer 312;

(3) forming a layer 316 of the first material with first index refraction, which is deposited using ion assist and with a thickness about 10 to 20 nm, to the layer 314;

(4) forming a layer 318 of the second material with second index refraction, with a thickness of about 50 to 70 nm, to the layer 316;

(5) forming a layer 320 of the first material with first index refraction, which is deposited using ion assist and with a thickness of about 25 to 40 nm, to the layer 318;

(6) forming a layer 322 of the second material with second index refraction, with a thickness of about 10 to 25 nm, to the layer 320; and

(7) forming a layer 324 of the first material with first index refraction, which is deposited using ion assist and with a thickness of about 5 to 15 nm, to the layer 322.

In one embodiment, the first index refraction L and the second index refraction H satisfy a ratio of H/L>1. In other words, the value of the second index refraction is greater than the value of the first index refraction.

In one embodiment as shown in FIG. 3, the first material with first index refraction comprises SiO₂, and the second material with second index refraction comprises ZrO₂.

In another aspect, the present invention relates to a mold with an optical surface having an anti-reflective coating that is transferable to an optical surface of a lens. In one embodiment as shown in FIG. 3, such a mold has:

a layer 305 of SiO₂ that is ion assisted with a thickness of 5 to 100 nm deposited to an optical surface 304 of the mold 302;

a layer 306 of a first hydrophobic material with a thickness of about 10 to 30 nm deposited to the layer 305;

a layer 308 of a second hydrophobic material with a thickness of about 10 to 50 nm deposited to the layer 306, wherein the first and second hydrophobic materials are different;

a layer 310 of SiO₂ that is deposited without using ion assist and with a thickness of about 5 to 40 nm deposited to the layer 308;

an anti-reflective coating layered structure 311 deposited to the layer 310; and

a layer 326 of a coupling agent that is deposited using vapor deposition and with a monolayer thickness deposited to the layer 324.

In one embodiment, the anti-reflective coating layered structure 311 has:

(1) a layer 312 of SiO₂ that is deposited using ion assist and with a thickness of about 5 to 100 nm deposited to the layer 310;

(2) a layer 314 of ZrO₂ with a thickness of about 40 to 50 nm deposited to the layer 312;

(3) a layer 316 of SiO₂ that is deposited using ion assist and with a thickness about 10 to 20 nm deposited to the layer 314;

(4) a layer 318 of ZrO₂ with a thickness of about 50 to 70 nm deposited to the layer 316;

(5) a layer 320 of SiO₂ that is deposited using ion assist and with a thickness of about 25 to 40 nm deposited to the layer 318;

(6) a layer 322 of ZrO₂ with a thickness of about 10 to 25 nm deposited to the layer 320; and

(7) a layer 324 of SiO₂ that is deposited using ion assist and with a thickness of about 5 to 15 nm deposited to the layer 322.

In one embodiment, the first hydrophobic material is a standard hydrophobic material, and the second hydrophobic material is a super hydrophobic material, respectively.

In one embodiment, the layer of coupling agent is formed of a composition that comprises cyclic azasilanes. In one particular embodiment, the layer of coupling agent is formed of N-n-butyl-aza-2,2-dimethoxy-silacyclopentane.

In one embodiment, the anti-reflective coating layered structure 311 is formed with:

(1) a layer 312 of a first material with first index refraction, which is deposited using ion assist and with a thickness of about 5 to 100 nm, deposited to the layer 310;

(2) a layer 314 of a second material with second index refraction, with a thickness of about 40 to 50 nm, deposited to the layer 312;

(3) a layer 316 of the first material with first index refraction, which is deposited using ion assist and with a thickness about 10 to 20 nm, deposited to the layer 314;

(4) a layer 318 of the second material with second index refraction, with a thickness of about 50 to 70 nm, deposited to the layer 316;

(5) a layer 320 of the first material with first index refraction, which is deposited using ion assist and with a thickness of about 25 to 40 nm, deposited to the layer 318;

(6) a layer 322 of the second material with second index refraction, with a thickness of about 10 to 25 nm, deposited to the layer 320; and

(7) a layer 324 of the first material with first index refraction, which is deposited using ion assist and with a thickness of about 5 to 15 nm, deposited to the layer 322.

In one embodiment, the first index refraction L and the second index refraction H satisfy a ratio of H/L>1. In other words, the value of the second index refraction is greater than the value of the first index refraction.

In one embodiment, the first material with first index refraction comprises SiO₂, and the second material with second index refraction comprises ZrO₂.

In yet another aspect, the present invention relates to an optical lens. In one embodiment, the optical lens has a lens body with an optical surface, and an anti-reflective coating formed on, or more specifically, transferred from a mold such as one set forth above to, the optical surface, where the anti-reflective coating is formed with:

a layer 305 of SiO₂ that is ion assisted with a thickness of 5 to 100 nm;

a layer 306 of a first hydrophobic material with a thickness of about 10 to 30 nm deposited to the layer 305;

a layer 308 of a second hydrophobic material with a thickness of about 10 to 50 nm deposited to the layer 306, wherein the first and second hydrophobic materials are different;

a layer 310 of SiO₂ that is deposited without using ion assist and with a thickness of about 5 to 40 nm deposited to the layer 308;

an anti-reflective coating layered structure 311 deposited to the layer 310; and

a layer 326 of a coupling agent that is deposited using vapor deposition and with a monolayer thickness deposited to the layer 324 and coupled to the optical surface.

In one embodiment as shown in FIG. 3, the anti-reflective coating layered structure 311 has:

(1) a layer 312 of SiO₂ that is deposited using ion assist and with a thickness of about 5 to 100 nm deposited to the layer 310;

(2) a layer 314 of ZrO₂ with a thickness of about 40 to 50 nm deposited to the layer 312;

(3) a layer 316 of SiO₂ that is deposited using ion assist and with a thickness about 10 to 20 nm deposited to the layer 314;

(4) a layer 318 of ZrO₂ with a thickness of about 50 to 70 nm deposited to the layer 316;

(5) a layer 320 of SiO₂ that is deposited using ion assist and with a thickness of about 25 to 40 nm deposited to the layer 318;

(6) a layer 322 of ZrO₂ with a thickness of about 10 to 25 nm deposited to the layer 320; and

(7) a layer 324 of SiO₂ that is deposited using ion assist and with a thickness of about 5 to 15 nm deposited to the layer 322.

In one embodiment, the first hydrophobic material is a standard hydrophobic material, and the second hydrophobic material is a super hydrophobic material, respectively.

In one embodiment, the layer of coupling agent is formed of a composition that comprises cyclic azasilanes. In one particular embodiment, the layer of coupling agent is formed of N-n-butyl-aza-2,2-dimethoxy-silacyclopentane.

Furthermore, in a more general embodiment, the optical lens has an anti-reflective coating layered structure 311 that is formed with:

(1) a layer 312 of a first material with first index refraction, which is deposited using ion assist and with a thickness of about 5 to 100 nm, deposited to the layer 310;

(2) a layer 314 of a second material with second index refraction, with a thickness of about 40 to 50 nm, deposited to the layer 312;

(3) a layer 316 of the first material with first index refraction, which is deposited using ion assist and with a thickness about 10 to 20 nm, deposited to the layer 314;

(4) a layer 318 of the second material with second index refraction, with a thickness of about 50 to 70 nm, deposited to the layer 316;

(5) a layer 320 of the first material with first index refraction, which is deposited using ion assist and with a thickness of about 25 to 40 nm, deposited to the layer 318;

(6) a layer 322 of the second material with second index refraction, with a thickness of about 10 to 25 nm, deposited to the layer 320; and

(7) a layer 324 of the first material with first index refraction, which is deposited using ion assist and with a thickness of about 5 to 15 nm, deposited to the layer 322.

In one embodiment, the first index refraction L and the second index refraction H satisfy a ratio of H/L>1. In other words, the value of the second index refraction is greater than the value of the first index refraction.

In one embodiment, the first material with first index refraction comprises SiO₂, and the second material with second index refraction comprises ZrO₂.

In a further aspect, the present invention relates to a method for making an anti-reflective coating to an optical surface of a mold. In various embodiments of the present invention as shown in FIGS. 3-6, such a method has the steps of:

providing a lens mold 302, 402, 502 or 602 having an optical surface 304, 404, 504 or 604;

forming a layer 306, 406, 506 or 606 of a first hydrophobic material with a thickness of about 10 to 50 nm over the optical surface 304, 404, 504 or 604;

forming a layer 308, 408, 508 or 608 of a second hydrophobic material with a thickness of about 10 to 50 nm over the layer 306, 406, 506 or 606, wherein the first and second hydrophobic materials are different;

forming an anti-reflective coating layered structure 311, 411, 511 or 611 over the layer 308, 408, 508 or 608; and

forming a layer 326, 426, 526 or 626 of a coupling agent that is deposited using vapor deposition and with a monolayer thickness over the anti-reflective coating layered structure 311, 411, 511 or 611.

The step of forming an anti-reflective coating layered structure 311, 411, 511 or 611 over the layer 308, 408, 508 or 608 can be performed with the steps of:

(1) forming a layer 312, 412, 512 or 612 of a first material with first index refraction and a thickness of about 5 to 100 nm over the layer 308, 408, 508 or 608;

(2) forming a layer 314, 414, 514 or 614 of a second material with second index refraction and a thickness of about 40 to 50 nm, to the layer 312, 412, 512 or 612;

(3) forming a layer 316, 416, 516 or 616 of the first material with first index refraction and a thickness about 10 to 20 nm, to the layer 314, 414, 514 or 614;

(4) forming a layer 318, 418, 518 or 618 of the second material with second index refraction and a thickness of about 50 to 70 nm, to the layer 316, 416, 516 or 616;

(5) forming a layer 320, 420, 520 or 620 of the first material with first index refraction and a thickness of about 25 to 40 nm, to the layer 318, 418, 518 or 618;

(6) forming a layer 322, 422, 522 or 622 of the second material with second index refraction and a thickness of about 10 to 25 nm, to the layer 320, 420, 520 or 620; and

(7) forming a layer 324, 424, 524 or 624 of the first material with first index refraction and a thickness of about 5 to 15 nm, to the layer 322, 422, 522 or 622.

In one embodiment, the first index refraction L and the second index refraction H satisfy a ratio of H/L>1. In other words, the value of the second index refraction is greater than the value of the first index refraction.

In one embodiment, the first material with first index refraction comprises SiO₂, and the second material with second index refraction comprises ZrO₂.

In one embodiment as shown in FIG. 3, prior to the step of forming a layer 306, 406, 506 or 606 of a first hydrophobic material with a thickness of 10 to 30 nm over the optical surface 304, 404, 504 or 604, a step of forming a layer 305 of SiO₂ that is ion assisted with a thickness of 5 to 100 nm over the optical surface 304 is performed such that the layer 305 is formed between the layer 306 and the optical surface 304.

Furthermore, in one embodiment as shown in FIG. 3, prior to the step of forming an anti-reflective coating layered structure 311, 411, 511 or 611 over the layer 308, 408, 508 or 608, a step of forming a layer 310 of SiO₂ that is deposited without ion assist and with a thickness of 5 to 40 nm over the layer 308 is performed such that the layer 310 is formed between the layer 308 and the layer 312.

In embodiments as shown in FIGS. 5 and 6, prior to the step of forming an anti-reflective coating layered structure 311, 411, 511 or 611 over the layer 308, 408, 508 or 608, a step of forming a layer 510, 610 of SiO₂ that is deposited without ion assist and with a thickness of 5 to 40 nm over the layer 508, 608 is performed such that the layer 510, 610 is formed between the layer 508, 608 and the layer 512, 612.

In practicing the present invention according to the methods set forth above, each layer of SiO₂ is deposited using ion assist or without using ion assist.

In one embodiment, the first hydrophobic material is a standard hydrophobic material, and the second hydrophobic material is a super hydrophobic material, respectively.

In one embodiment, the layer of coupling agent is formed of a composition that comprises cyclic azasilanes. In one particular embodiment, the layer of coupling agent is formed of N-n-butyl-aza-2,2-dimethoxy-silacyclopentane.

In yet another aspect, the present invention relates to a mold with an optical surface having an anti-reflective coating that is transferable to an optical surface of a lens. In various embodiments as shown in FIGS. 3-6, such a mold has:

a layer 306, 406, 506 or 606 of a first hydrophobic material with a thickness of about 10 to 30 nm deposited over an optical surface 304, 404, 504 or 604 the mold 302, 402, 502 or 602;

a layer 308, 408, 508 or 608 of a second hydrophobic material with a thickness of about 10 to 50 nm deposited over the layer 306, 406, 506 or 606, wherein the first and second hydrophobic materials are different;

an anti-reflective coating layered structure 311, 411, 511 or 611 deposited over the layer 308, 408, 508 or 608; and

a layer 326, 426, 526 or 626 of a coupling agent that is deposited using vapor deposition and with a monolayer thickness deposited over the anti-reflective coating layered structure 311, 411, 511 or 611.

As shown in FIGS. 3-6, the anti-reflective coating layered structure 311, 411, 511 or 611 has:

(1) a layer 312, 412, 512 or 612 of a first material with first index refraction and a thickness of about 5 to 100 nm deposited over the layer 308, 408, 508 or 608;

(2) a layer 314, 414, 514 or 614 of a second material with second index refraction and a thickness of about 40 to 50 nm, deposited to the layer 312, 412, 512 or 612;

(3) a layer 316, 416, 516 or 616 of the first material with first index refraction and a thickness about 10 to 20 nm, deposited to the layer 314, 414, 514 or 614;

(4) a layer 318, 418, 518 or 618 of the second material with second index refraction and a thickness of about 50 to 70 nm, deposited to the layer 316, 416, 516 or 616;

(5) a layer 320, 420, 520 or 620 of the first material with first index refraction and a thickness of about 25 to 40 nm, deposited to the layer 318, 418, 518 or 618;

(6) a layer 322, 422, 522 or 622 of the second material with second index refraction and a thickness of about 10 to 25 nm, deposited to the layer 320, 420, 520 or 620; and

(7) a layer 324, 424, 524 or 624 of the first material with first index refraction and a thickness of about 5 to 15 nm, deposited to the layer 322, 422, 522 or 622.

The first index refraction L and the second index refraction H satisfy a ratio of H/L>1. In other words, the value of the second index refraction is greater than the value of the first index refraction.

In one embodiment, the first material with first index refraction comprises SiO₂, and the second material with second index refraction comprises ZrO₂.

In one embodiment as shown in FIG. 3, moreover, a layer 305 of SiO₂ that is ion assisted with a thickness of 5 to 100 nm is deposited over the optical surface 304 such that the layer 305 is formed between the layer 306 and the optical surface 304. Additionally, a layer 310 of SiO₂ is deposited without ion assist and with a thickness of 5 to 40 nm over the layer 308 such that the layer 310 is formed between the layer 308 and the layer 312.

In various embodiments as shown in FIGS. 5 and 6, alternatively, a layer 510, 610 of SiO₂ is deposited without ion assist and with a thickness of 5 to 40 nm over the layer 508, 608 such that the layer 510, 610 is formed between the layer 508, 608 and layer 512, 612.

Each layer of SiO₂ is deposited using ion assist or without using ion assist.

The first hydrophobic material is a standard hydrophobic material, and the second hydrophobic material is a super hydrophobic material, respectively.

The layer of coupling agent is formed of a composition that comprises cyclic azasilanes. In various embodiments as shown in FIGS. 3-6, the layer of coupling agent is formed of N-n-butyl-aza-2,2-dimethoxy-silacyclopentane.

In a further aspect, the present invention relates to an optical lens. The optical lens has a lens body with an optical surface and an anti-reflective coating formed on the optical surface, where in various embodiments as shown in FIGS. 3-6, the anti-reflective coating has:

a layer 306, 406, 506 or 606 of a first hydrophobic material with a thickness of about 10 to 30 nm deposited over an optical surface 304, 404, 504 or 604 the mold 302, 402, 502 or 602;

a layer 308, 408, 508 or 608 of a second hydrophobic material with a thickness of about 10 to 50 nm deposited over the layer 306, 406, 506 or 606, wherein the first and second hydrophobic materials are different;

an anti-reflective coating layered structure 311, 411, 511 or 611 deposited over the layer 308, 408, 508 or 608; and

a layer 326, 426, 526 or 626 of a coupling agent that is deposited using vapor deposition and with a monolayer thickness deposited over the anti-reflective coating layered structure 311, 411, 511 or 611 and coupled to the optical surface.

The anti-reflective coating layered structure 311, 411, 511 or 611 is formed with:

(1) a layer 312, 412, 512 or 612 of a first material with first index refraction and a thickness of about 5 to 100 nm deposited over the layer 308, 408, 508 or 608;

(2) a layer 314, 414, 514 or 614 of a second material with second index refraction and a thickness of about 40 to 50 nm, deposited to the layer 312, 412, 512 or 612;

(3) a layer 316, 416, 516 or 616 of the first material with first index refraction and a thickness about 10 to 20 nm, deposited to the layer 314, 414, 514 or 614;

(4) a layer 318, 418, 518 or 618 of the second material with second index refraction and a thickness of about 50 to 70 nm, deposited to the layer 316, 416, 516 or 616;

(5) a layer 320, 420, 520 or 620 of the first material with first index refraction and a thickness of about 25 to 40 nm, deposited to the layer 318, 418, 518 or 618;

(6) a layer 322, 422, 522 or 622 of the second material with second index refraction and a thickness of about 10 to 25 nm, deposited to the layer 320, 420, 520 or 620; and

(7) a layer 324, 424, 524 or 624 of the first material with first index refraction and a thickness of about 5 to 15 nm, deposited to the layer 322, 422, 522 or 622.

The first index refraction L and the second index refraction H satisfy a ratio of H/L>1. In other words, the value of the second index refraction is greater than the value of the first index refraction.

In various embodiments as shown in FIGS. 3-6, the first material with first index refraction comprises SiO₂, and the second material with second index refraction comprises ZrO₂.

In one embodiment as shown in FIG. 3, a layer 305 of SiO₂ that is ion assisted with a thickness of 5 to 100 nm is deposited over the optical surface 304 such that the layer 305 is formed between the layer 306 and the optical surface 304. Moreover, a layer 310 of SiO₂ that is deposited without ion assist and with a thickness of 5 to 40 nm over the layer 308 such that the layer 310 is formed between the layer 308 and the layer 312.

In various embodiments as shown in FIGS. 5 and 6, a layer 510, 610 of SiO₂ that is deposited without ion assist and with a thickness of 5 to 40 nm over the layer 508, 608 such that the layer 510, 610 is formed between the layer 508, 608 and the layer 512, 612.

In yet another aspect, the present invention relates to a coupling agent usable in lens making. In one embodiment, the coupling agent comprises cyclic azasilanes. In one specific embodiment, cyclic azasilanes comprise N-n-butyl-aza-2,2-dimethoxy-silacyclopentane. It is noted that in use, cyclic azasilanes are applied in a solvent. For embodiments as shown in FIGS. 3-6, where SiO₂ is used as the first material with first index refraction, utilizing N-n-butyl-aza-2,2-dimethoxy-silacyclopentane as a coupling agent allows a surface bonding ring opening reaction without requiring water or heat, as shown in FIG. 2, resulting much better bonding and making the on-site AR lens forming a reality, which is much better than the process shown in FIG. 1 that requires high heat and water, among other things.

It is further noted that in practicing the present invention, the steps for each embodiment given above can be performed in sequence as given, or in different orders.

In a further aspect, the present invention relates to an optical lens. In one embodiment, the optical lens has a lens body with an optical surface, a hard coat layer over the optical surface, and an anti-reflective coating over the optical surface.

In one embodiment, the anti-reflective coating has a layer of a coupling agent with a monolayer thickness over the hard coat layer, an anti-reflective coating layered structure over the layer of a coupling agent, a second layer of SiO₂ that is deposited without using ion assist and with a thickness of about 5 to 40 nm over the anti-reflective coating layered structure over the layer of a coupling agent, and a layer of a hydrophobic material over the second layer of SiO₂. The layer of a hydrophobic material may include a first hydrophobic material and a second hydrophobic material, wherein the first and second hydrophobic materials are different, and wherein the first hydrophobic material is a standard hydrophobic material, and the second hydrophobic material is a super hydrophobic material, respectively.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A method for making an anti-reflective coating to an optical surface of a mold, comprising the steps of:
(a) providing a lens mold having an optical surface;
(b) forming a first layer of SiO₂ that is ion assisted with a thickness of 5 to 100 nm to the optical surface;
(c) forming a layer of a first hydrophobic material with a thickness of about 10 to 30 nm to the layer;
(d) forming a layer of a second hydrophobic material with a thickness of about 10 to 50 nm to the layer of a first hydrophobic material, wherein the first and second hydrophobic materials are different;
(e) forming a second layer of SiO₂ that is deposited without using ion assist and with a thickness of about 5 to 40 nm to the layer of a second hydrophobic material;
(f) forming an anti-reflective coating layered structure over the second layer of SiO₂; and
(g) forming a layer of a silane coupling agent that is deposited using vapor deposition under aprotic conditions and with a monolayer thickness to the anti-reflective coating layered structure.

2. The method of claim 1, wherein the step of forming an anti-reflective coating layered structure to the second layer of SiO₂ further comprises the steps of:
(a) forming a third layer of SiO₂ that is deposited using ion assist and with a thickness of about 5 to 100 nm to the second layer of SiO₂;
(b) forming a first layer of ZrO₂ with a thickness of about 40 to 50 nm to the third layer of SiO₂;
(c) forming a fourth layer of SiO₂ that is deposited using ion assist and with a thickness about 10 to 20 nm to the first layer of ZrO₂;
(d) forming a second layer of ZrO₂ with a thickness of about 50 to 70 nm to the fourth layer of SiO₂;
(e) forming a fifth layer of SiO₂ that is deposited using ion assist and with a thickness of about 25 to 40 nm to the second layer of ZrO₂;
(f) forming a third layer of ZrO₂ with a thickness of about 10 to 25 nm to the fifth layer of SiO₂; and
(g) forming a sixth layer of SiO₂ that is deposited using ion assist and with a thickness of about 5 to 15 nm to the third layer of ZrO₂.

3. The method of claim 1, wherein the first hydrophobic material is a standard hydrophobic material, and the second hydrophobic material is a super hydrophobic material, respectively.

4. The method of claim 1, wherein the layer of silane coupling agent is formed of a composition that comprises cyclic azasilanes.

5. The method of claim 4, wherein the layer of a silane coupling agent is formed of N-n-butyl-aza-2,2-dimethoxy-silacyclopentane.

6. The method of claim 1, wherein the step of forming an anti-reflective coating layered structure to the second layer of SiO₂ further comprises the steps of:
(a) forming a first layer of a first material with first index refraction, which is deposited using ion assist and with a thickness of about 5 to 100 nm, to the second layer of SiO₂;
(b) forming a second layer of a second material with second index refraction, with a thickness of about 40 to 50 nm, to the first layer of the first material;
(c) forming a third layer of the first material with first index refraction, which is deposited using ion assist and with a thickness about 10 to 20 nm, to the second layer of the second material;
(d) forming a fourth layer of the second material with second index refraction, with a thickness of about 50 to 70 nm, to the third layer;
(d) forming a fifth layer of the first material with first index refraction, which is deposited using ion assist and with a thickness of about 25 to 40 nm, to the fourth layer;
(f) forming a sixth layer of the second material with second index refraction, with a thickness of about 10 to 25 nm, to the fifth layer; and
(g) forming a seventh layer of the first material with first index refraction, which is deposited using ion assist and with a thickness of about 5 to 15 nm, to the sixth layer.

7. The method of claim 6, wherein the first index refraction L and the second index refraction H satisfy a ratio of H/L>1.

8. The method of claim 7, wherein the first material with first index refraction comprises SiO₂, and the second material with second index refraction comprises ZrO₂.

9. A mold with an optical surface having an anti-reflective coating that is transferable to an optical surface of a lens, comprising:
(a) a first layer of SiO₂ that is ion assisted with a thickness of 5 to 100 nm deposited to an optical surface of the mold;
(b) a layer of a first hydrophobic material with a thickness of about 10 to 30 nm deposited to the first layer of SiO₂;
(c) a layer of a second hydrophobic material with a thickness of about 10 to 50 nm deposited to the layer of a first hydrophobic material, wherein the first and second hydrophobic materials are different;
(d) a second layer of SiO₂ that is deposited without using ion assist and with a thickness of about 5 to 40 nm deposited to the layer of a second hydrophobic material;
(e) an anti-reflective coating layered structure deposited to the second layer of SiO₂; and
(f) a layer of a coupling agent that is deposited using vapor deposition and with a monolayer thickness deposited over the anti-reflective coating layered structure.

10. The mold of claim 9, wherein the anti-reflective coating layered structure comprises:
(a) a third layer of SiO₂ that is deposited using ion assist and with a thickness of about 5 to 100 nm deposited to the second layer of SiO₂;
(b) a first layer of ZrO₂ with a thickness of about 40 to 50 nm deposited to the third layer of SiO₂;
(c) a fourth layer of SiO₂ that is deposited using ion assist and with a thickness about 10 to 20 nm deposited to the first layer of ZrO₂;
(d) a second layer of ZrO₂ with a thickness of about 50 to 70 nm deposited to the fourth layer of SiO₂;
(d) a fifth layer of SiO₂ that is deposited using ion assist and with a thickness of about 25 to 40 nm deposited to the second layer of ZrO₂;
(f) a third layer of ZrO₂ with a thickness of about 10 to 25 nm deposited to the fifth layer of SiO₂; and
(g) a sixth layer of SiO₂ that is deposited using ion assist and with a thickness of about 5 to 15 nm deposited to the third layer of ZrO₂.

11. The mold of claim 9, wherein the first hydrophobic material is a standard hydrophobic material, and the second hydrophobic material is a super hydrophobic material, respectively.

12. The mold of claim 9, wherein the layer of coupling agent is formed of a composition that comprises cyclic azasilanes.

13. The mold of claim 12, wherein the layer of coupling agent is formed of N-n-butyl-aza-2,2-dimethoxy-silacyclopentane.

14. The mold of claim 9, wherein the anti-reflective coating layered structure comprises:
(a) a first layer of a first material with first index refraction, which is deposited using ion assist and with a thickness of about 5 to 100 nm, deposited to the second layer of SiO₂;
(b) a second layer of a second material with second index refraction, with a thickness of about 40 to 50 nm, deposited to the first layer of the first material;
(c) a third layer of the first material with first index refraction, which is deposited using ion assist and with a thickness about 10 to 20 nm, deposited to the second layer of the second material;
(d) a fourth layer of the second material with second index refraction, with a thickness of about 50 to 70 nm, deposited to the third layer;
(e) a fifth layer of the first material with first index refraction, which is deposited using ion assist and with a thickness of about 25 to 40 nm, deposited to the fourth layer;
(f) a sixth layer of the second material with second index refraction, with a thickness of about 10 to 25 nm, deposited to the fifth layer; and
(g) a seventh layer of the first material with first index refraction, which is deposited using ion assist and with a thickness of about 5 to 15 nm, deposited to the sixth layer.

15. The mold of claim 14, wherein the first index refraction L and the second index refraction H satisfy a ratio of H/L>1.

16. The mold of claim 15, wherein the first material with first index refraction comprises SiO₂, and the second material with second index refraction comprises ZrO₂.

17. An optical lens, comprising:
(1) a lens body with an optical surface;
(2) a hard coat layer over the optical surface; and
(3) an anti-reflective coating over the optical surface, wherein the anti-reflective coating comprises:
(a) a layer of a coupling agent with a monolayer thickness over the hard coat layer;
(b) an anti-reflective coating layered structure over the layer of a coupling agent;
(c) a second layer of SiO₂ that is deposited without using ion assist and with a thickness of about 5 to 40 nm over the anti-reflective coating layered structure over the layer of a coupling agent; and
(d) a layer of a hydrophobic material over the second layer of SiO₂.

18. The optical lens of claim 17, wherein the anti-reflective coating layered structure comprises:
(a) a third layer of SiO₂ that is deposited using ion assist and with a thickness of about 5 to 100 nm deposited to the second layer SiO₂;
(b) a first layer of ZrO₂ with a thickness of about 40 to 50 nm deposited to the third layer of SiO₂;
(c) a fourth layer of SiO₂ that is deposited using ion assist and with a thickness about 10 to 20 nm deposited to the first layer of ZrO₂;
(d) a second layer of ZrO₂ with a thickness of about 50 to 70 nm deposited to the fourth layer of SiO₂;
(e) a fifth layer of SiO₂ that is deposited using ion assist and with a thickness of about 25 to 40 nm deposited to the second layer of ZrO₂;
(f) a third layer of ZrO₂ with a thickness of about 10 to 25 nm deposited to the fifth layer of SiO₂; and
(g) a sixth layer of SiO₂ that is deposited using ion assist and with a thickness of about 5 to 15 nm deposited to the third layer of ZrO₂.

19. The optical lens of claim 17, wherein the layer of a hydrophobic material comprises a first hydrophobic material and a second hydrophobic material, wherein the first and second hydrophobic materials are different, and wherein the first hydrophobic material is a standard hydrophobic material, and the second hydrophobic material is a super hydrophobic material, respectively.

20. The optical lens of claim 17, wherein the layer of coupling agent is formed of a composition that comprises cyclic azasilanes.

21. The optical lens of claim 20, wherein the layer of coupling agent is formed of N-n-butyl-aza-2,2-dimethoxy-silacyclopentane.

22. The optical lens of claim 17, wherein the anti-reflective coating layered structure comprises:
(a) a first layer of a first material with first index refraction, which is deposited using ion assist and with a thickness of about 5 to 100 nm, deposited to the second layer of SiO₂;
(b) a second layer of a second material with second index refraction, with a thickness of about 40 to 50 nm, deposited to the first layer of the first material;
(c) a third layer of the first material with first index refraction, which is deposited using ion assist and with a thickness about 10 to 20 nm, deposited to the second layer of the second material;
(d) a fourth layer of the second material with second index refraction, with a thickness of about 50 to 70 nm, deposited to the third layer;
(e) a fifth layer of the first material with first index refraction, which is deposited using ion assist and with a thickness of about 25 to 40 nm, deposited to the fourth layer;
(f) a sixth layer of the second material with second index refraction, with a thickness of about 10 to 25 nm, deposited to the fifth layer; and
(g) a seventh layer of the first material with first index refraction, which is deposited using ion assist and with a thickness of about 5 to 15 nm, deposited to the sixth layer.

23. The optical lens of claim 22, wherein the first index refraction L and the second index refraction H satisfy a ratio of H/L>1.

24. The optical lens of claim 23, wherein the first material with first index refraction comprises SiO₂, and the second material with second index refraction comprises ZrO₂.

25. A method for making an anti-reflective coating to an optical surface of a mold, comprising the steps of:
(a) providing a lens mold having an optical surface;
(b) forming a layer of a first hydrophobic material with thickness of about 10 to 30 nm over the optical surface;
(c) forming a layer of a second hydrophobic material with a thickness of about 10 to 50 nm over the layer of a first hydrophobic material, wherein the first and second hydrophobic materials are different;
(d) forming an anti-reflective coating layered structure over the layer of a second hydrophobic material; and
(e) forming a layer of a coupling agent that is deposited using vapor deposition and with a monolayer thickness over the anti-reflective coating layered structure.

26. The method of claim 25, wherein the step of forming an anti-reflective coating layered structure over the layer further comprises the steps of:
(a) forming a first layer of a first material with first index refraction and a thickness of about 5 to 100 nm over the layer of a second hydrophobic material;
(b) forming a second layer of a second material with second index refraction and a thickness of about 40 to 50 nm, to the first layer;
(c) forming a third layer of the first material with first index refraction and a thickness about 10 to 20 nm, to the second layer;
(d) forming a fourth layer of the second material with second index refraction and a thickness of about 50 to 70 nm, to the third layer;
(e) forming a fifth layer of the first material with first index refraction and a thickness of about 25 to 40 nm, to the fourth layer;
(f) forming a sixth layer of the second material with second index refraction and a thickness of about 10 to 25 nm, to the fifth layer; and
(g) forming a seventh layer of the first material with first index refraction and a thickness of about 5 to 15 nm, to the sixth layer.

27. The method of claim 26, wherein the first index refraction L and the second index refraction H satisfy a ratio of H/L>1.

28. The method of claim 27, wherein the first material with first index refraction is SiO₂, and the second material with second index refraction is ZrO₂.

29. The method of claim 28, prior to the step of forming a layer of a first hydrophobic material with a thickness of about 10 to 30 nm over the optical surface, further comprising a step of forming an eighth layer of SiO₂ that is ion assisted with a thickness of 5 to 100 nm over the optical surface such that the eighth layer of SiO₂ is formed between the layer of a first hydrophobic material and the optical surface.

30. The method of claim 29, prior to the step of forming an anti-reflective coating layered structure over the layer of a second hydrophobic material, further comprising a step of forming a ninth layer of SiO₂ that is deposited without ion assist and with a thickness of 5 to 40 nm over the layer of a second hydrophobic material such that the ninth layer of SiO₂ is formed between the layer of a second hydrophobic material and the first layer of the first material.

31. The method of claim 28, prior to the step of forming an anti-reflective coating layered structure over the layer of a second hydrophobic material, further comprising a step of forming a layer of SiO₂ that is deposited without ion assist and with a thickness of 5 to 40 nm over the layer of a second hydrophobic material such that the layer of SiO₂ is formed between the layer of a second hydrophobic material and the first layer of the first material.

32. The method of claim 28, wherein each layer of SiO₂ is deposited using ion assist or without using ion assist.

33. The method of claim 25, wherein the first hydrophobic material is a standard hydrophobic material, and the second hydrophobic material is a super hydrophobic material, respectively.

34. The method of claim 25, wherein the layer of coupling agent is formed of a composition that comprises cyclic azasilanes.

35. The method of claim 34, wherein the layer of coupling agent is formed of N-n-butyl-aza-2,2-dimethoxy-silacyclopentane.

36. A mold with an optical surface having an anti-reflective coating that is transferable to an optical surface of a lens, comprising:
(a) a layer of a first hydrophobic material with a thickness of about 10 to 30 nm deposited over an optical surface of the mold;
(b) a layer of a second hydrophobic material with a thickness of about 10 to 50 nm deposited over the layer of a first hydrophobic material, wherein the first and second hydrophobic materials are different;
(c) an anti-reflective coating layered structure deposited over the layer of a second hydrophobic material; and
(d) a layer of a coupling agent that is deposited using vapor deposition and with a monolayer thickness deposited over the anti-reflective coating layered structure.

37. The mold of claim 36, wherein the anti-reflective coating layered structure comprises:
(a) a first layer of a first material with first index refraction and a thickness of about 5 to 100 nm deposited over the layer of a second hydrophobic material;
(b) a second layer of a second material with second index refraction and a thickness of about 40 to 50 nm, deposited to the first layer;
(c) a third layer of the first material with first index refraction and a thickness about 10 to 20 nm, deposited to the second layer;
(d) a fourth layer of the second material with second index refraction and a thickness of about 50 to 70 nm, deposited to the third layer;
(e) a fifth layer of the first material with first index refraction and a thickness of about 25 to 40 nm, deposited to the fourth layer;
(f) a sixth layer of the second material with second index refraction and a thickness of about 10 to 25 nm, deposited to the fifth layer; and
(g) a seventh layer of the first material with first index refraction and a thickness of about 5 to 15 nm, deposited to the sixth layer.

38. The mold of claim 37, wherein the first index refraction L and the second index refraction H satisfy a ratio of H/L >1.

39. The mold of claim 38, wherein the first material with first index refraction is SiO₂, and the second material with second index refraction is ZrO₂.

40. The mold of claim 39, further comprising a layer of SiO₂ that is ion assisted with a thickness of 5 to 100 nm and deposited over the optical surface such that the layer of SiO₂ is formed between the layer of a first hydrophobic material and the optical surface.

41. The mold of claim 40, further comprising a layer of SiO₂ that is deposited without ion assist and with a thickness of 5 to 40 nm and over the layer of a second hydrophobic material such that the layer of SiO₂ is formed between the layer of a second hydrophobic material and the first layer of the first material.

42. The mold of claim 39, further comprising a layer of SiO₂ that is deposited without ion assist and with a thickness of 5 to 40 nm over the layer of a second hydrophobic material such that the layer of SiO₂ is formed between the layer of a second hydrophobic material and the first layer of the first material.

43. The mold of claim 39, wherein each layer of SiO₂ is deposited using ion assist or without using ion assist.

44. The mold of claim 36, wherein the first hydrophobic material is a standard hydrophobic material, and the second hydrophobic material is a super hydrophobic material, respectively.

45. The mold of claim 36, wherein the layer of coupling agent is formed of a composition that comprises cyclic azasilanes.

46. The mold of claim 45, wherein the layer of coupling agent is formed of N-n-butyl-aza-2,2-dimethoxy-silacyclopentane.

47. An optical lens, comprising:
(i) a lens body with an optical surface; and
(ii) an anti-reflective coating formed on the optical surface, wherein the anti-reflective coating comprises:
(a) a layer of a first hydrophobic material thickness of about 10 to 30 nm deposited over an optical surface of the mold;
(b) a layer of a second hydrophobic material with a thickness of about 10 to 50 nm deposited over the layer of a first hydrophobic material, wherein the first and second hydrophobic materials are different;
(c) an anti-reflective coating layered structure deposited over the layer of a second hydrophobic material; and
(d) a layer of a coupling agent that is deposited using vapor deposition and with a monolayer thickness deposited over the anti-reflective coating layered structure and coupled to the optical surface.

48. The optical lens of claim 47, wherein the anti-reflective coating layered structure comprises:
(a) a first layer of a first material with first index refraction and a thickness of about 5 to 100 nm deposited over the layer of a second hydrophobic material;
(b) a second layer of a second material with second index refraction and a thickness of about 40 to 50 nm, deposited to the first layer;
(c) a third layer of the first material with first index refraction and a thickness about 10 to 20 nm, deposited to the second layer;
(d) a fourth layer of the second material with second index refraction and a thickness of about 50 to 70 nm, deposited to the third layer;
(e) a fifth layer of the first material with first index refraction and a thickness of about 25 to 40 nm, deposited to the fourth layer;
(f) a sixth layer of the second material with second index refraction and a thickness of about 10 to 25 nm, deposited to the fifth layer; and
(g) a seventh layer of the first material with first index refraction and a thickness of about 5 to 15 nm, deposited to the sixth layer.

49. The optical lens of claim 48, wherein the first index refraction L and the second index refraction H satisfy a ratio of H/L>1.

50. The optical lens of claim 49, wherein the first material with first index refraction is SiO₂, and the second material with second index refraction is ZrO₂.

51. The optical lens of claim 50, further comprising a layer of SiO₂ that is ion assisted with a thickness of 5 to 100 nm and deposited over the optical surface such that the layer of SiO₂ is formed between the layer of a first hydrophobic material and the optical surface.

52. The optical lens of claim 51, further comprising a layer of SiO₂ that is deposited without ion assist and with a thickness of 5 to 40 nm and over the layer of a second hydrophobic material such that the layer of SiO₂ is formed between the layer of a second hydrophobic material and the first layer of the first material.

53. The optical lens of claim 50, further comprising a layer of SiO₂ that is deposited without ion assist and with a thickness of 5 to 40 nm over the layer of a second hydrophobic material such that the layer of SiO₂ is formed between the first layer of the first material and the layer of a second hydrophobic material.

54. The optical lens of claim 50, wherein each layer of SiO₂ is deposited using ion assist or without using ion assist.

55. A coupling agent usable in lens making, comprising cyclic azasilanes.

56. The coupling agent of claim 55, wherein cyclic azasilanes comprise N-n-butyl-aza-2,2-dimethoxy-silacyclopentane.

57. The coupling agent of claim 55, wherein in use, cyclic azasilanes are applied in a solvent.
